(19) United States
(12) Patent Application Publication
(10) Pub. No.: US 2026/0032882 A1
(43) Pub. Date: Jan. 29, 2026

(54) MICROELECTRONIC DEVICES, AND RELATED METHODS OF FORMING MICROELECTRONIC DEVICES

(71) Applicant: Micron Technology, Inc., Boise, ID (US)

(72) Inventors: Eyob N. Tarekegn, Meridian, ID (US); Kolya Yastrebenetsky, Boise, ID (US); David A. Daycock, Boise, ID (US)

(21) Appl. No.: 19/255,574

(22) Filed: Jun. 30, 2025

Related U.S. Application Data
(60) Provisional application No. 63/676,679, filed on Jul. 29, 2024.

(51) Int. Cl. H10B 12/00; H01L 23/00; H01L 25/065; H01L 25/18; H10B 80/00; H10D 62/83; H10D 62/832; H10D 80/30

(52) U.S. Cl. CPC H10B 12/05; H01L 24/05; H01L 24/08; H01L 24/80; H01L 25/0657; H01L 25/18; H10B 12/03; H10B 12/30; H10B 80/00; H10D 62/83; H10D 62/832; H10D 80/30; H01L 2224/05541; H01L 2224/08145; H01L 2224/80896; H01L 2924/1436

(57) ABSTRACT

A microelectronic device includes a first microelectronic device structure and a second microelectronic device structure vertically underlying the first microelectronic device structure. The first microelectronic device structure includes a stack structure and a first insulative material vertically underlying the stack structure. The stack structure includes tiers vertically stacked relative to one another and respectively including a first semiconductor material, and a second semiconductor material vertically neighboring the first semiconductor material. The second microelectronic device structure includes a second insulative material and a base semiconductor structure. The second insulative material is bonded to the first insulative material of the first microelectronic device structure. The base semiconductor structure is at least partially vertically adjacent to and in physical contact with the second insulative material. Related methods, memory devices, and electronic systems are also described.

### CROSS-REFERENCE TO RELATED APPLICATIONS

This application claims the benefit under 35 U.S.C. § 119(e) of U.S. Provisional Patent Application Ser. No. 63/676,679, filed Jul. 29, 2024, the disclosure of which is hereby incorporated herein in its entirety by this reference.

### TECHNICAL FIELD

This disclosure, in various embodiments, relates generally to the field of microelectronic device design and fabrication. More specifically, this disclosure relates to methods of forming microelectronic devices from independently formed microelectronic device structures, and to related microelectronic devices and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but that also offer performance advantages, as well as simplified, easier, and less expensive to fabricate designs.

One example of a microelectronic device is a memory device. Memory devices are generally provided as internal integrated circuits in computers or other electronic devices. There are many types of memory devices including, but not limited to, volatile memory devices, such as dynamic random-access memory (DRAM) devices; and non-volatile memory devices such as NAND Flash memory devices. A typical memory cell of a DRAM device includes one access device, such as a transistor, and one memory storage structure, such as a capacitor. Modern applications for semiconductor devices can employ significant quantities of memory cells arranged in memory arrays exhibiting rows and columns of memory cells. The memory cells may be electrically accessed through digit lines (e.g., bit lines, data lines) and word lines (e.g., access lines) arranged along the rows and columns of memory cells of the memory arrays. Memory arrays can be two-dimensional (2D) so as to exhibit a single deck (e.g., a single tier, a single level) of memory cells, or can be three-dimensional (3D) so as to exhibit multiple decks (e.g., multiple levels, multiple tiers) of memory cells.

Three-dimensional (3D) memory cells may be configured as vertical stacks of access devices (e.g., transistors) in electrical communication with vertical stacks of storage devices (e.g., capacitors) to form vertical stacks of memory cells. Processing conditions (e.g., temperatures, pressures, materials) for the formation of arrays of vertical stacks of memory cells can limit the configuration and performance of the microelectronic device in which such arrays of memory cells are inserted. In particular, the formation of high aspect ratio trenches may present challenges in the manufacturing process of memory devices. Furthermore, insulating epitaxially-grown, crystalline, silicon structures from a carrier substrate may also present challenges in the manufacturing process of memory devices.

### BRIEF DESCRIPTION OF THE DRAWINGS

For a detailed understanding of the disclosure, reference should be made to the following detailed descriptions, taken in conjunction with the accompanying drawings, in which like elements have generally been designated with like numerals, and wherein:

FIGS. 1A through 1E are simplified, partial, vertical, cross-sectional views illustrating a method of forming a microelectronic device, in accordance with embodiments of the disclosure.

FIGS. 2A through 2E are simplified, partial, vertical, cross-sectional views illustrating an additional method of forming a microelectronic device, in accordance with additional embodiments of the disclosure.

FIGS. 3A and 3B are simplified, partial, vertical, cross-sectional views and block diagram illustrating a microelectronic device at a processing stage subsequent to the methods of forming a microelectronic device previously described, in accordance with additional embodiments of the disclosure.

FIG. 4 is a schematic block diagram of an electronic system, according to one or more embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures described herein may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional non-volatile memory, conventional volatile memory), but also includes an application specific integrated circuit (ASIC) (e.g., a system on a chip (SoC)), a microelectronic device combining logic and memory, and a graphics processing unit (GPU) incorporating memory.

As used herein, the terms “configured” and “configuration” refer to a size, shape, material composition, material distribution, orientation, and/or arrangement of at least one feature (e.g., one or more of at least one structure, at least one material, at least one region, at least one device) facilitating the use of at least one other feature in a pre-determined way.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes a degree of variance, such as within acceptable manufacturing tolerances, that one of ordinary skill in the art would understand that the given parameter, property, or condition is met. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, relational terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the drawings. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, the term “and/or” means and includes any and all combinations of one or more of the associated listed items.

As used herein, the terms “vertical,” “longitudinal,” “horizontal,” and “lateral” are in reference to a major plane of a structure and are not necessarily defined by the Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the drawings, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fc), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such as one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H₂)), and at least one dielectric carboxynitride material (e.g., a silicon carboxynitride (SiOₓC₂N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10-8 Siemens per centimeter (S/cm) and about 10+S/cm (106 S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, each of a “semiconductor structure” and a “semiconductive structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, a semiconductor material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly and/or parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

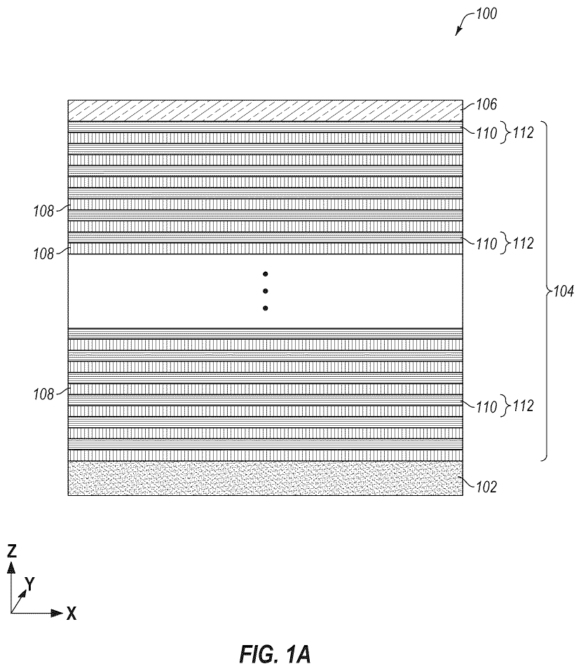

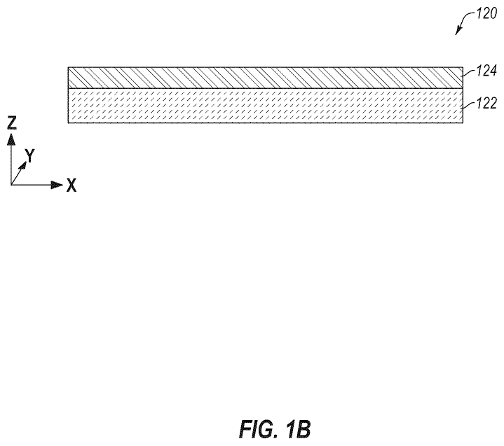

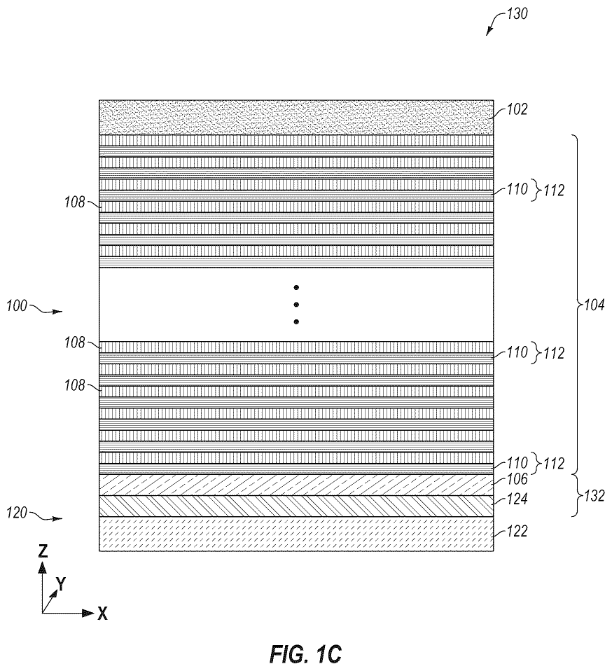

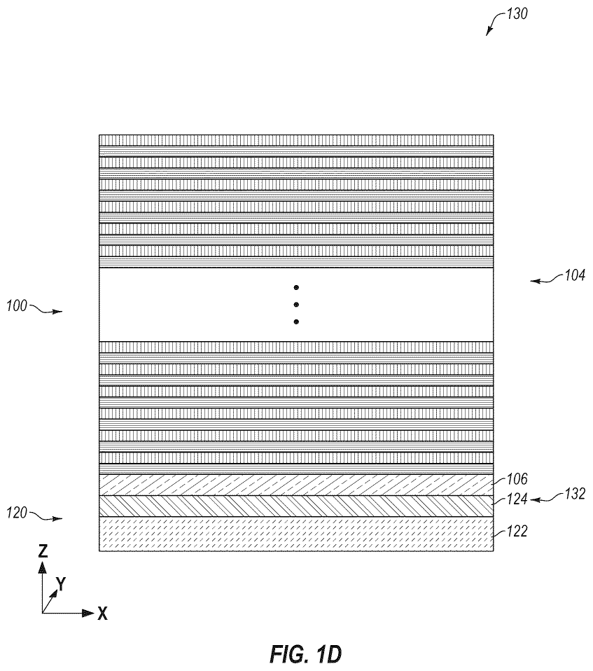

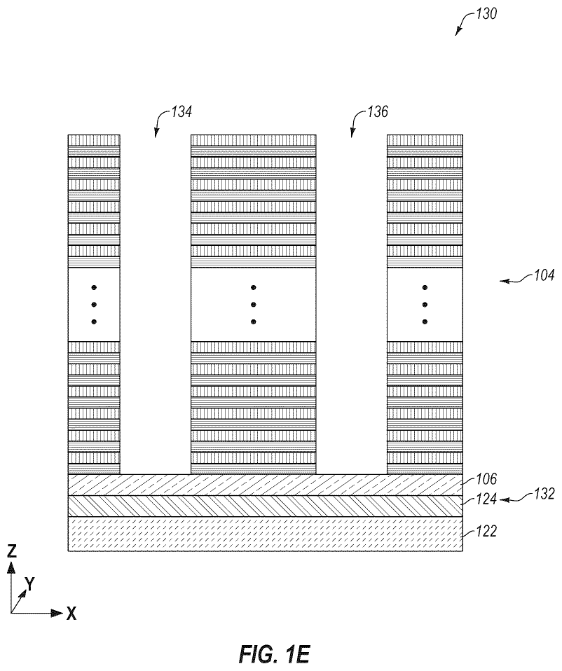

FIG. 1A through FIG. 1E are simplified, partial, vertical, cross-sectional views illustrating embodiments of microelectronic device structures in processing stages of a method of forming a microelectronic device (e.g., a memory device, such as a non-volatile memory device, or a volatile memory device). With the descriptions provided below, it will be readily apparent to one of ordinary skill in the art that the methods and structures described herein may be used in various devices and electronic systems.

Referring to FIG. 1A, a first microelectronic device structure 100 may be formed to include a first base structure 102, a vertical (e.g., in the Z-direction) stack structure 104 comprising a vertically alternating sequence of a first material 108 and a second material 110 arranged in tiers 112, and a first insulative material 106. The stack structure 104 may be formed on or over the first base structure 102. The first insulative material 106 may be formed on or over the stack structure 104.

The first base structure 102 may include a semiconductor structure (e.g., a semiconductor wafer) or a base semiconductor material on a supporting structure. For example, the first base structure 102 may include a conventional silicon substrate (e.g., a conventional silicon wafer), or another bulk substrate including a semiconductor material, or a combination thereof. As used herein, the term “bulk substrate” means and includes not only silicon substrates, but also silicon-on-insulator (SOI) substrates, such as silicon-on-sapphire (SOS) substrates and silicon-on-glass (SOG) substrates; epitaxial layers of silicon on a semiconductor base; and other substrates formed of and including one or more semiconductor materials (e.g., one or more of a silicon material, such as monocrystalline silicon or polycrystalline silicon; silicon-germanium; germanium; gallium arsenide; gallium nitride; indium phosphide). In some embodiments, the first base structure 102 comprises a silicon wafer. In addition, the first base structure 102 may include one or more layers, structures, devices, and/or regions formed therein and/or thereon (e.g., control logic circuitry structures, memory array structures, doped and undoped regions).

Processing conditions (e.g., temperatures, pressures, materials) for the formation of the first base structure 102 may be chosen to advantageously facilitate (e.g., minimize costs, defects, contamination, and/or enable certain crystallographic characteristics) the epitaxial growth of the stack structure 104 according to the first material 108, second material 110, and/or desired crystallographic characteristics (e.g., anisotropy, Miller Indices, atomic packing factors (APF)).

Although FIG. 1A illustrates only twelve (12) tiers 112 (six bottom tiers 112 separated from six top tiers 112 by a vertical ellipsis), the disclosure is not so limited. It will be understood that the stack structure 104 may be formed to include any desired number of the tiers 112. By way of non-limiting example, the stack structure 104 may be formed to include more than twelve (12) of the tiers 112, such as greater than or equal to fourteen (14) of the tiers 112, greater than or equal to sixteen (16) of the tiers 112, greater than or equal to thirty-two (32) of the tiers 112, greater than or equal to sixty-four (64) of the tiers 112, or greater than or equal to eighty (80) of the tiers 112. In other embodiments, the stack structure 104 may be formed to include less than twelve (12) of the tiers 112, such as less than or equal to four (4) of the tiers 112. In some embodiments, the stack structure 104 is formed to include more than eighty (80) of the tiers 112.

Each of the tiers 112 of the stack structure 104 may be formed to have substantially the same vertical height as each other of the tiers 112 of the stack structure 104, or one or more of the tiers 112 of the stack structure 104 may individually be formed to have a different vertical height than one or more other of the tiers 112 of the stack structure 104. In some embodiments, each of the tiers 112 of the stack structure 104 is formed to have substantially the same vertical height as each other of the tiers 112 of the stack structure 104.

In some embodiments, the tiers 112 are respectively formed to include the first material 108 underlying the second material 110. In other embodiments, the orders of the first material 108 and the second material 110 are switched, such that the tiers 112 respectively include the second material 110 underlying the first material 108. In addition, the stack structure 104 may contain one or more of the tier 112 variations described herein. For example, the stack structure 104 may contain some (e.g., a first group) of the tiers 112 formed of and including the first material 108 underlying the second material 110, and some others (e.g., a second group) of the tiers 112 formed of and including the second material 110 underlying the first material 108.

The second material 110 of each of the tiers 112 of the stack structure 104 may be formed of and include at least one material that may be selectively removed relative to the first material 108. The second material 110 may be selectively etchable relative to the first material 108 during common (e.g., collective, mutual) exposure to a first etchant; and the first material 108 may be selectively etchable to the second material 110 during common exposure to a second, different etchant. As used herein, a material is “selectively etchable” relative to another material if the material exhibits an etch rate that is at least about five times (5×) greater than the etch rate of another material, such as about ten times (10×) greater, about twenty times (20×) greater, or about forty times (40×) greater.

The first material 108 of respective ones of the tiers 112 of the stack structure 104 may be formed of and include a first semiconductor material (e.g., silicon). The first material 108 may, for example, be formed of and include silicon, such as monocrystalline silicon or polycrystalline silicon. In some embodiments, the first material 108 is formed of and includes epitaxially grown silicon, such as epitaxial monocrystalline silicon or epitaxial polycrystalline silicon. In additional embodiments, the first material 108 of respective ones of the tiers 112 is formed of and includes a different semiconductor material, such as material including Si and Ge (SiGe).

The second material 110 of respective ones of the tiers 112 of the stack structure 104 may be formed of and include a second semiconductor material having a different material composition than the first material 108. If the first material 108 is formed of and includes Si, the second material 110 may, for example, be formed of and include SiGe. In some embodiments, the second material 110 is formed of and includes epitaxially grown SiGe (“epitaxial SiGe”). In other embodiments, such as where the first material 108 is formed of and includes SiGe, the second material 110 is formed of and includes Si (e.g., epitaxially grown Si, such as epitaxial monocrystalline Si or epitaxial polycrystalline Si).

The first insulative material 106 may be formed of and include one or more of at least one dielectric oxide material (e.g., one or more of a silicon oxide (SiOₓ), phosphosilicate glass, borosilicate glass, borophosphosilicate glass (BPSG), fluorosilicate glass, a titanium oxide (TiOₓ), a zirconium oxide (ZrOₓ), a hafnium oxide (HfOₓ), a tantalum oxide (TaOₓ), a magnesium oxide (MgOₓ), an aluminum oxide (AlOₓ), a niobium oxide (NbOₓ), a molybdenum oxide (MoOₓ), a strontium oxide (SrOₓ), a barium oxide (BaOₓ), an yttrium oxide (YOₓ), or a combination thereof), at least one dielectric nitride material (e.g., a silicon nitride (SiN_{y})), at least one dielectric oxynitride material (e.g., a silicon oxynitride (SiOₓN_{y})), at least one dielectric carbon nitride material (e.g., a silicon carbon nitride (SiC_{y}Nₓ)), at least one dielectric carboxynitride material (e.g., a silicon carboxynitride (SiOₓC_{z}N_{y})), at least one dielectric oxycarbide material (e.g., a silicon oxycarbide (SiCₓO_{y})), and at least one dielectric hydrogenated oxycarbide material (e.g., a hydrogenated silicon oxycarbide (SiCₓO_{y}H_{z})). In some embodiments, the first insulative material 106 is formed of and includes a dielectric oxide material, such as silicon dioxide (SiO₂). The first insulative material 106 may be substantially homogeneous, or may be heterogeneous.

The first insulative material 106 may be formed to a desired vertical height (e.g., in the Z-direction). As a non-limiting example, the first insulative material 106 may be formed to have a vertical height within a range of from about 100 nanometers (nm) to about 200 nm, such as from about 140 nm to about 200 nm, or from about 120 nm to about 180 nm. In some embodiments, the first insulative material 106 is formed to have a vertical height of about 140 nm.

Still referring to FIG. 1A, the first insulative material 106 may be configured to facilitate the attachment (e.g., bonding) of the first microelectronic device structure 100 to a second microelectronic device structure, as described in further detail below. For example, the first insulative material 106 may be configured to facilitate subsequent dielectric-to-dielectric (e.g., oxide-to-oxide, oxycarbide-to-oxycarbide, oxycarbide-to-oxide, carbonitride-to-carbonitride) bonding between the first microelectronic device structure 100 and the second microelectronic device structure.

Referring to FIG. 1B, a second microelectronic device structure 120 may be formed separate from the first microelectronic device structure 100. The second microelectronic device structure 120 may be formed to include a second base structure 122 and a second insulative material 124. The second insulative material 124 may be formed on or over the second base structure 122.

The second base structure 122 may comprise a base construction upon which additional features (e.g., materials, structures, devices) of the second microelectronic device structure 120 are formed or attached (e.g., bonded). The second base structure 122 may, for example, be a semiconductor structure (e.g., a semiconductor wafer) or a base semiconductor material on a supporting structure. The second base structure 122 may be a conventional silicon substrate (e.g., a conventional silicon wafer), or another bulk substrate comprising a semiconductor material, or a combination thereof. As used herein, the term “bulk substrate” means and includes not only silicon substrates, but also silicon-on-insulator (SOI) substrates, such as silicon-on-sapphire (SOS) substrates and silicon-on-glass (SOG) substrates; epitaxial layers of silicon on a semiconductor base; and other substrates formed of and including one or more semiconductor materials (e.g., one or more of a silicon material, such as monocrystalline silicon or polycrystalline silicon; silicon-germanium; germanium; gallium arsenide; gallium nitride; gallium phosphide; indium phosphide; indium gallium nitride; aluminum gallium nitride). In addition, the second base structure 122 may include one or more layers, structures, devices, and/or regions formed or attached (e.g., bonded) therein and/or thereon (e.g., control logic circuitry structures, control logic device structures, CMOS structures, memory array structures, access device structures, doped and undoped regions, digit lines structures, word line structures, interconnect structures). As a non-limiting example, the second base structure 122 may include a control circuitry structure including control logic circuitry. As another non-limiting example, the second base structure 122 may include a memory array structure (e.g., a non-volatile memory array structure, a volatile memory array structure) including an array of memory cells (e.g., an array of non-volatile memory cells, an array of volatile memory cells). A material composition and/or configuration of the second base structure 122 of the second microelectronic device structure 120 may be substantially different than a material composition and/or configuration of the first base structure 102 of the first microelectronic device structure 100 (FIG. 1A); or the material composition and/or configuration of the second base structure 122 of the second microelectronic device structure 120 may be substantially the same as the material composition and/or configuration of the first base structure 102 of the first microelectronic device structure 100 (FIG. 1A). In some embodiments, the second base structure 122 comprises a silicon wafer.

The second insulative material 124 may be formed of and include one or more of at least one dielectric oxide material (e.g., one or more of SiOₓ, phosphosilicate glass, borosilicate glass, BPSG, fluorosilicate glass, TiOₓ, ZrOₓ, HfOₓ, TaOₓ, MgOₓ, AlOₓ, NbOₓ, MoOₓ, SrOₓ, BaOₓ, and YOₓ), at least one dielectric nitride material (e.g., SiN_{y}), at least one dielectric oxynitride material (e.g., SiOₓN_{y}), at least one dielectric carbon nitride material (e.g., SiC_{y}Nₓ), at least one dielectric carboxynitride material (e.g., SiOₓC_{z}N_{y}), at least one dielectric oxycarbide material (e.g., SiCₓO_{y}), and at least one dielectric hydrogenated oxycarbide material (e.g., SiCₓO_{y}H₂). In some embodiments, the second insulative material 124 is formed of and includes a dielectric oxide material, such as SiO₂. The second insulative material 124 may be substantially homogeneous, or may be heterogeneous. In some embodiments, the second insulative material 124 is substantially homogeneous. A material composition of the second insulative material 124 of the second microelectronic device structure 120 may be substantially the same as a material composition of the first insulative material 106 of the first microelectronic device structure 100 (FIG. 1A); or the material composition of the second insulative material 124 of the second microelectronic device structure 120 may be different than the material composition of the first insulative material 106 of the first microelectronic device structure 100 (FIG. 1A).

The second insulative material 124 may be formed to a desired vertical height (e.g., length in the Z-direction). A vertical height of the second insulative material 124 of the second microelectronic device structure 120 may be substantially the same as the vertical height of the first insulative material 106 of the first microelectronic device structure 100 (FIG. 1A); or the vertical height of the second insulative material 124 of the second microelectronic device structure 120 may be different than the vertical height of the first insulative material 106 of the first microelectronic device structure 100 (FIG. 1A). As a non-limiting example, the second insulative material 124 may be formed to have a vertical height within a range of from about 100 nm to about 200 nm, such as from about 140 nm to about 200 nm, or from about 120 nm to about 180 nm. In some embodiments, the second insulative material 124 is formed to have a vertical height of about 140 nm.

Still referring to FIG. 1B, the second insulative material 124 may be configured to facilitate the attachment (e.g., bonding) of the second microelectronic device structure 120 to the first microelectronic device structure 100 (FIG. 1A), as described in further detail below with reference to FIG. 1C. For example, the second insulative material 124 may be configured to facilitate subsequent dielectric-to-dielectric (e.g., oxide-to-oxide, oxycarbide-to-oxycarbide, carboxynitride-to-carboxynitride, oxycarbide-to-oxide, carboxynitride-to-oxide, carbonitride-to-carbonitride, carboxynitride-to-carbonitride) bonding between the second microelectronic device structure 120 and the first microelectronic device structure 100 (FIG. 1A).

Referring next to FIG. 1C, the first microelectronic device structure 100 may be vertically (e.g., in the Z-direction) inverted (e.g., flipped) and attached (e.g., bonded) to the second microelectronic device structure 120 to form a third microelectronic device structure 130 (e.g., an assembly). As shown in FIG. 1C, the third microelectronic device structure 130 may be formed to include the first microelectronic device structure 100 (including the first base structure 102, the stack structure 104 (comprising a vertically alternating sequence of the first material 108 and the second material 110 arranged in tiers 112), and the first insulative material 106), as vertically inverted, over and bonded to the second microelectronic device structure 120 (including the second insulative material 124 and the second base structure 122). Alternatively, the second microelectronic device structure 120 may be vertically inverted (e.g., flipped) and attached (e.g., bonded) to the first microelectronic device structure 100 to form the third microelectronic device structure 130, and thereafter the third microelectronic device structure 130 may be vertically inverted to arrive at the orientation thereof depicted in FIG. 1C. A bonded insulative material formed by bonding the first insulative material 106 to the second insulative material 124 is referred to herein as a third insulative material 132.

To form the third microelectronic device structure 130, the first insulative material 106 of the first microelectronic device structure 100 may be provided in physical contact with the second insulative material 124 of the second microelectronic device structure 120, and then the first insulative material 106 and the second insulative material 124 may be exposed to annealing conditions to form the dielectric-to-dielectric bonds (e.g., one or more of oxide-to-oxide bonds, oxycarbide-to-oxycarbide bonds, carboxynitride-to-carboxynitride bonds, oxycarbide-to-oxide bonds, carboxynitride-to-oxide bonds, carbonitride-to-carbonitride bonds, carboxynitride-to-carbonitride bonds) between the first insulative material 106 and the second insulative material 124. By way of non-limiting example, the first insulative material 106 and the second insulative material 124 may be exposed to a temperature greater than or equal to about 400° C. (e.g., within a range of from about 400° C. to about 800° C., greater than about 800° C.) to form bonds between the first insulative material 106 and the second insulative material 124. In some embodiments, the first insulative material 106 and the second insulative material 124 are exposed to at least one temperature greater than about 800° C. to form oxide-to-oxide bonds between the first insulative material 106 and the second insulative material 124.

Providing the first microelectronic device structure 100 and the second microelectronic device structure 120 in physical contact with one another ahead of bonding the first microelectronic device structure 100 and the second microelectronic device structure 120 to form the third microelectronic device structure 130 may include facilitating one or more different arrangements (e.g., positions, orientations, alignments) of the first microelectronic device structure 100 relative to the second microelectronic device structure 120. By way of non-limiting example, the first microelectronic device structure 100 may or may not be horizontally rotated (e.g., positivity horizontally rotated, negatively horizontally rotated) about an axis (e.g., an axis parallel to the Z-direction) relative to the second microelectronic device structure 120, or vice versa. One or more of the second microelectronic device structure 120 and the first microelectronic device structure 100 may include alignment markers to facilitate desired arrangements of features of the second microelectronic device structure 120 and the first microelectronic device structure 100 ahead of bonding the second microelectronic device structure 120 and the first microelectronic device structure 100.

While FIG. 1C, FIG. 1D, and FIG. 1E depict the third insulative material 132 as two individual shaded regions (one shaded region representing the first insulative material 106 and the other shaded region representing the second insulative material 124) before the bonding process, the third insulative material 132 may be integral and continuous following the bonding process (e.g., the first microelectronic device structure 100 may be attached to the second microelectronic device structure 120 without a bond line; no interface material is formed between the first insulative material 106 and the second insulative material 124). The third insulative material 132 may be substantially homogeneous, or the third insulative material 132 may be at least partially heterogeneous. In some embodiments, the third insulative material 132 is formed of and includes the first insulative material 106 bonded to the second insulative material 124 without a bond line. In other embodiments, the third insulative material 132 is formed of and includes the first insulative material 106 bonded to the second insulative material 124 with a bond line. In yet other embodiments, bonding of the first insulative material 106 and the second insulative material 124 forms an interface material between remaining portions of the first insulative material 106 and the second insulative material 124, and the interface material has a different material composition than each of the first insulative material 106 and the second insulative material 124. For example, if the first insulative material 106 and the second insulative material 124 respectively include dielectric oxycarbide material, bonding the first insulative material 106 and the second insulative material 124 may form a dielectric oxide interface material between the first insulative material 106 and the second insulative material 124 within the third insulative material 132.

The third insulative material 132 of the third microelectronic device structure 130 may be formed to a desired vertical height (e.g., in the Z-direction). The third insulative material 132 may have a vertical height substantially equal to combined vertical heights of the first insulative material 106 and the second insulative material 124. For example, if the first insulative material 106 and the second insulative material 124 are each formed to a vertical height of about 100 nm, the third insulative material 132 may have a vertical height of about 200 nm. As a non-limiting example, the third insulative material 132 may be formed to have a vertical height (equal to the combined vertical heights of the first insulative material 106 and the second insulative material 124) within a range of from about 200 nm to about 300 nm, such as from about 220 nm to about 300 nm, or from about 240 nm to about 280 nm. In some embodiments, the third insulative material 132 is formed to have a vertical height of about 300 nm (e.g., the first insulative material 106 is formed to a vertical height of about 100 nm and the second insulative material 124 is formed to a vertical height of about 200 nm; the first insulative material 106 is formed to a vertical height of about 180 nm and the second insulative material 124 is formed to a vertical height of about 120 nm).

Referring to FIG. 1D, the first base structure 102 of the third microelectronic device structure 130 may be substantially removed (e.g., using one or more of dry etching, wet etching, ion milling, CMP, laser ablation, smart cutting, and another material removal process). In some embodiments, following the formation of the third microelectronic device structure 130, the first base structure 102 is the vertically (e.g., in the Z-direction) uppermost material of the third microelectronic device structure 130, and a CMP process is used to substantially remove the first base structure 102 of the third microelectronic device structure 130. In other embodiments, following the formation of the third microelectronic device structure 130, the first base structure 102 is the vertically (e.g., in the Z-direction) lowermost material of the third microelectronic device structure 130, and a laser ablation process is used to remove the first base structure 102 of the third microelectronic device structure 130.

Referring next to FIG. 1E, a first trench 134 and a second trench 136 may respectively be formed to vertically extend (e.g., in the Z-direction) through the stack structure 104 of the third microelectronic device structure 130. The first trench 134 and the second trench 136 may be horizontally offset from one another, and may respectively vertically extend to or into the third insulative material 132. As described in further detail below, the third insulative material 132 may serve as an etch stop material during the formation of the first trench 134 and the second trench 136, and may also electrically isolate the second base structure 122 from features (e.g., materials, structures, circuitry, devices) subsequently formed within the first trench 134 and the second trench 136.

The first trench 134 and the second trench 136 may respectively be formed using at least one etching process, such as an anisotropic etching process (e.g., a deep reactive ion etching (DRIE)) that removes portions of the stack structure 104. As previously mentioned, the third insulative material 132 may serve as an etch stop material for the etching process. Following the etching process, portions of the third insulative material 132 may be exposed by the first trench 134 and the second trench 136. Exposed surfaces of the stack structure 104 and the third insulative material 132 may at least partially define boundaries (e.g., horizontal boundaries, vertical boundaries) of the first trench 134 and the second trench 136.

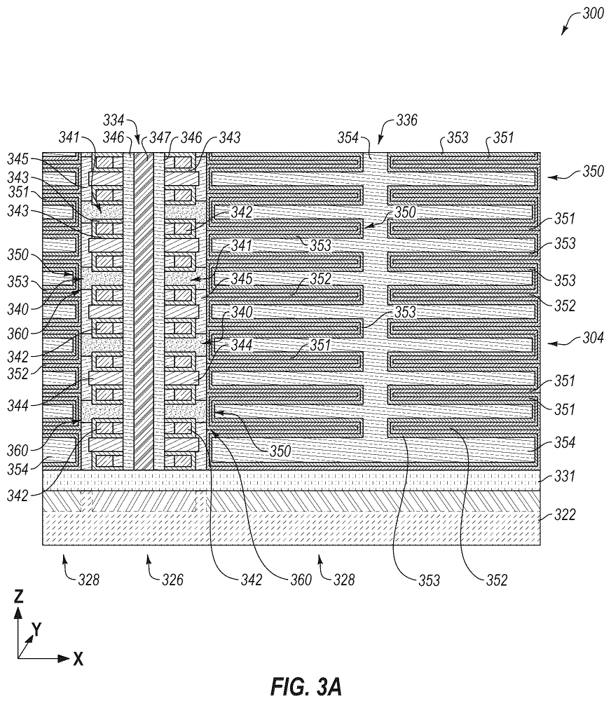

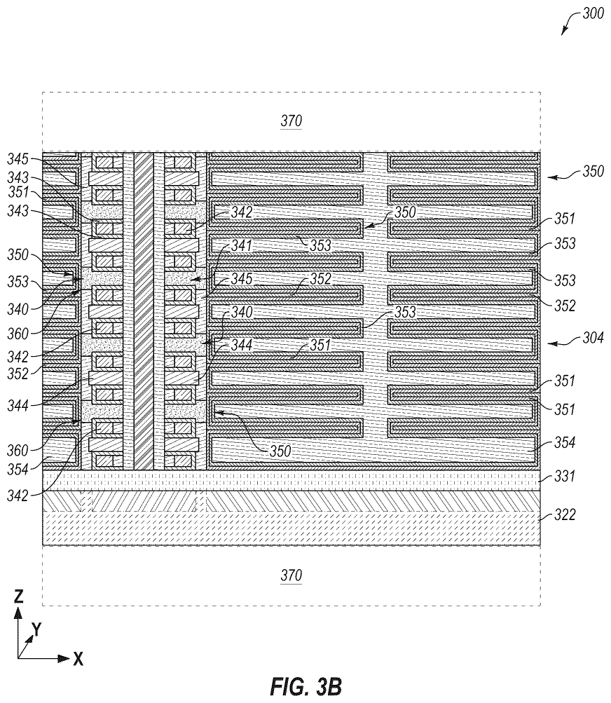

The first trench 134 and the second trench 136 may respectively be formed to have desired horizontal cross-sectional dimensions (e.g., a length in the Y-direction, a width in the X-direction) and a desired horizontal cross-sectional shape. As a non-limiting example, the first trench 134 may be formed to have horizontal dimensions that facilitate additional processing of the third microelectronic device structure 130 to form a vertical (e.g., in the Z-direction) stack of access devices 340 (FIG. 3A, FIG. 3B) within the stack structure 104 of the third microelectronic device structure 130. As another non-limiting example, the second trench 136 may be formed to have horizontal dimensions that facilitate additional processing of the third microelectronic device structure 130 to form a vertical (e.g., in the Z-direction) stack of storage devices 350 (FIG. 3A, FIG. 3B) within the stack structure 104 of the third microelectronic device structure 130. Horizontal dimensions (and, hence, a horizontal area) of the second trench 136 may be substantially equal to horizontal dimensions (and, hence, a horizontal area) of the first trench 134 of the third microelectronic device structure 130; or one or more horizontal dimensions (e.g., a length, a width) (and, potentially, a horizontal area) of the second trench 136 may be different than one or more corresponding horizontal dimensions (e.g., a length, a width) (and, potentially, a horizontal area) of the first trench 134 of the third microelectronic device structure 130.

An etching process for the formation of the second trench 136 of the third microelectronic device structure 130 may be substantially the same as an etching process for the formation of the first trench 134 of the third microelectronic device structure 130; or the etching process for the formation of the second trench 136 of the third microelectronic device structure 130 may be different than the etching process for the formation of the first trench 134 of the third microelectronic device structure 130. In some embodiments, the first trench 134 and the second trench 136 are formed concurrently (e.g., simultaneously, using the same etching process). In other embodiments, the first trench 134 and the second trench 136 are formed separately (e.g., using different etching processes).

The first trench 134 and the second trench 136 may respectively horizontally extend in a first direction (e.g., in the Y-direction), and may be horizontally spaced from one another in a second direction (e.g., in the X-direction) orthogonal to the first direction. In some embodiments, the second trench 136 and the first trench 134 horizontally extend in parallel in the Y-direction. In addition, the second trench 136 may be at least partially horizontally offset from the first trench 134 in the Y-direction, or the second trench 136 may substantially horizontally overlap the first trench 134 in the Y-direction.

Following the formation of the first trench 134 and the second trench 136, the third microelectronic device structure 130 may be subject to additional processing, as desired. As a non-limiting example, a vertical stack of access devices 340 (FIG. 3A and FIG. 3B), and/or a vertical stack of storage devices 350 (FIG. 3A and FIG. 3B), and/or interconnect structures (e.g., digit lines, word lines, contact structures) may be formed within the third microelectronic device structure 130 to form arrays of memory cells 360 (FIG. 3A and FIG. 3B). As an additional non-limiting example, so-called “back-end-of-line” (BEOL) structures (e.g., routing structures, pad structures, contact structures) (FIG. 3B) and/or control logic devices (e.g., array multiplexers (MUX), decoders (e.g., local I/O devices), sense amplifiers, error checking and correction (ECC) devices) (FIG. 3B) may be formed and/or attached (e.g., bonded) over the third microelectronic device structure 130, as desired. While FIG. 1E shows the third microelectronic device structure 130 as being formed upon the attachment of the first microelectronic device structure 100 to the second microelectronic device structure 120, the formation of the first trench 134, and the formation of the second trench 136, it will be understood that such additional processing may be implemented to finalize or ready the third microelectronic device structure 130 for inclusion in a relatively larger device and/or electronic system.

The method of forming the third microelectronic device structure 130 described herein may facilitate the formation of a relatively high-quality (e.g., epitaxially grown on the first base structure 102), relatively thick (e.g., vertical height in the Z-direction greater than or equal to the vertical stacking of eighty (80) tiers 112), crystalline, lattice structure (e.g., the stack structure 104) on insulator substrate (e.g., the third insulative material 132 overlying the second base structure 122) as compared to conventional methods. Furthermore, the method of forming the third microelectronic device structure 130 described herein may facilitate the concurrent (e.g., during the same etching process) or separate (e.g., during different etching processes) formation of high aspect ratio trenches (e.g., the first trench 134, the second trench 136) through an epitaxially grown, relatively thick, crystalline, lattice structure (e.g., the stack structure 104) without undesirable substrate (e.g., the second base structure 122) compromise (e.g., penetration) due to excessive etch depth (e.g., breakthrough of an etch-stop barrier). Moreover, the method of forming the third microelectronic device structure 130 described herein may resolve limitations on substrate (e.g., second base structure 122) configurations (e.g., structures, devices, circuitry) and associated device performance that may otherwise result from thermal budget constraints imposed by the formation and/or processing of an epitaxially grown, relatively thick, crystalline, lattice structure (e.g., the stack structure 104).

Additionally, the third insulative material 132 of the third microelectronic device structure 130, as formed through the methods of the disclosure, may electrically isolate the second base structure 122 from features (e.g., regions, materials, structures, devices) formed within the stack structure 104, to avoid undesired electrical shorting of such features by way of the second base structure 122. In some embodiments, such as FIG. 3A and FIG. 3B, memory cell arrays (e.g., vertical stacks of memory cells) and digit lines (e.g., bit lines, data lines) are formed within the stack structure 104 of the third microelectronic device structure 130, and the third insulative material 132 of the third microelectronic device structure 130 electrically isolates the second base structure 122 from one or more of digit lines, conductive contacts (e.g., digit line contacts), and storage node devices (e.g., capacitors) of memory cells (e.g., volatile memory cells, such as DRAM cells) formed within the stack structure 104 of the third microelectronic device structure 130. Accordingly, the third insulative material 132 of the third microelectronic device structure 130 mitigates (e.g., substantially prevents) the risk of undesirable electrical interactions (e.g., shorting) between conductive features (e.g., of one digit line with another digit line, of one capacitor electrode with another capacitor electrode, and/or of one digit line with a capacitor electrode) by way of the second base structure 122.

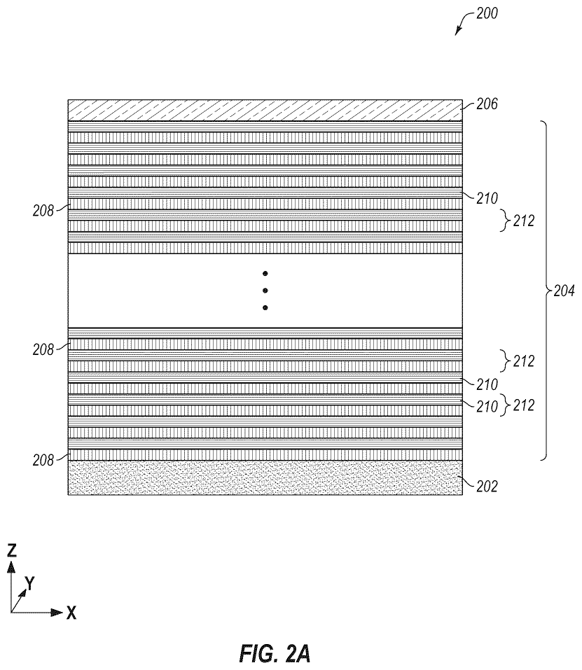

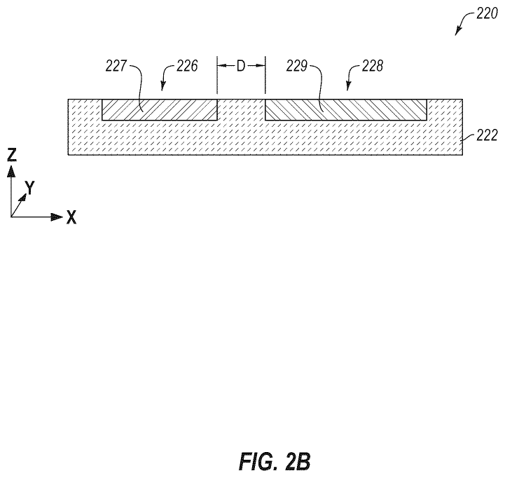

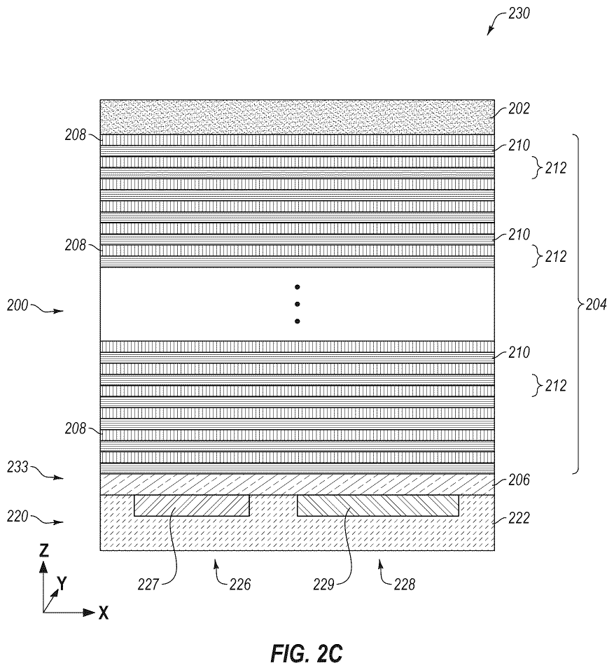

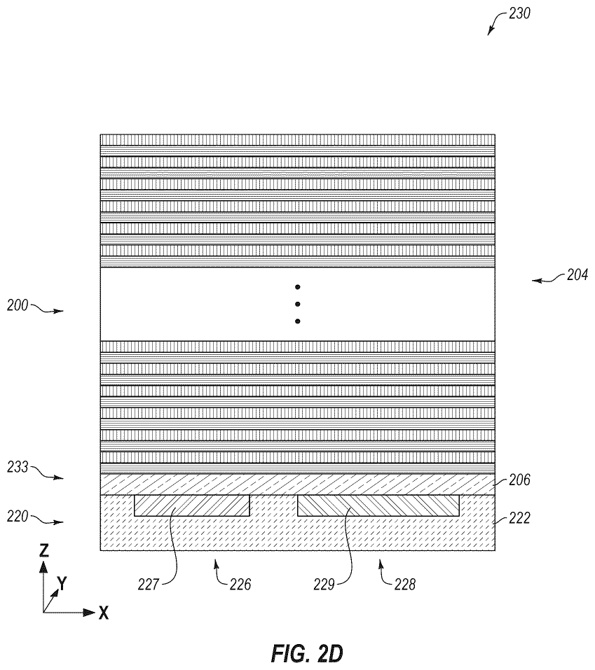

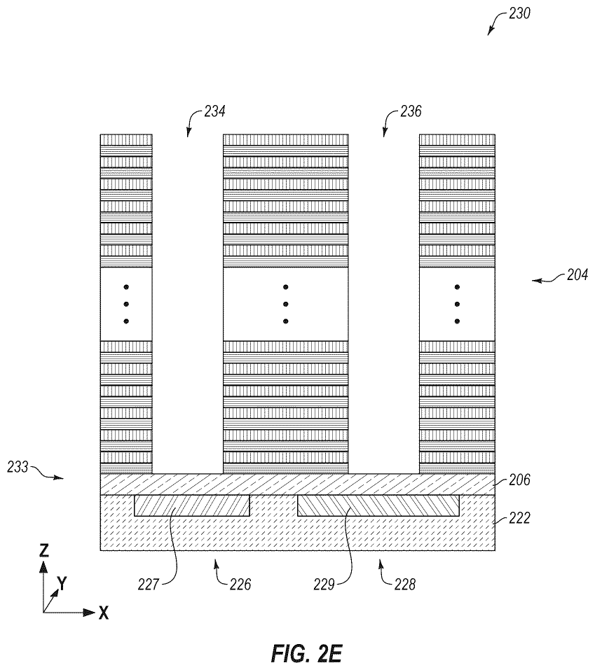

In additional embodiments, a microelectronic device structure of the disclosure is formed to have a different configuration than the third microelectronic device structure 130 at the processing stage depicted in FIG. 1E. By way of non-limiting example, FIG. 2A through FIG. 2E are simplified, partial, vertical, cross-sectional views illustrating embodiments of microelectronic device structures in processing stages of an additional method of forming a microelectronic device (e.g., a memory device, such as a non-volatile memory device, or a volatile memory device). The additional method of forming a microelectronic device incorporates some of the processing acts and some of the features previously described, with reference to FIG. 1A through FIG. 1E, in relation to the formation of the third microelectronic device structure 130 (FIG. 1E). The processing stages depicted in FIG. 2A through FIG. 2E and described in further detail below may, for example, include various processing acts performed in place of and/or in combination with the processing acts previously described, with reference to FIG. 1A through FIG. 1E, to form the third microelectronic device structure 130 (FIG. 1E). Throughout FIG. 2A to FIG. 2E and the associated description below, features (e.g., structures, materials, regions, devices) functionally similar to features previously described with reference to one or more of FIG. 1A through FIG. 1E are referred to with similar reference numerals incremented by 100. To avoid repetition, not all features shown in FIG. 2A through FIG. 2E are described in detail herein. Rather, unless described otherwise, in FIG. 2A through FIG. 2E, a feature designated by a reference numeral that is a 100 increment of the reference numeral of a feature previously described with reference to one or more of FIG. 1A through FIG. 1E will be understood to be substantially similar to the previously described feature.

Referring to FIG. 2A, a first microelectronic device structure 200 may be formed to include features (e.g., structures, materials, regions, devices) substantially similar to and formed in substantially the same manner as the features (e.g., structures, materials, regions, devices) of the first microelectronic device structure 100 at the processing stage previously described with reference to FIG. 1A. As shown in FIG. 2A, the first microelectronic device structure 200 may be formed to include a first base structure 202, a stack structure 204 including a vertically alternating sequence of a first material 208 and a second material 210 arranged in tiers 212, and a first insulative material 206. The stack structure 204 may be formed on or over the first base structure 202. The first insulative material 206 may be formed on or over the stack structure 204.

Alternatively, the first microelectronic device structure 200 may be formed without the first insulative material 206. In such embodiments, the first insulative material 206 is formed on or over the stack structure 204 of the first microelectronic device structure 200 in a subsequent processing stage, such subsequent processing stage preceding a subsequent bonding processing stage.

Referring next to FIG. 2B, a second microelectronic device structure 220 may be formed separate from the first microelectronic device structure 200. The second microelectronic device structure 220 may include features substantially similar to and formed in substantially the same manner as corresponding features of the second microelectronic device structure 120 at the processing stage previously described with reference to FIG. 1B, except that in place of the second insulative material 124 (FIG. 1B) formed over the second base structure 122, the second microelectronic device structure 220 is formed to include a first isolation structure 226 and a second isolation structure 228 formed within the second base structure 222. The first isolation structure 226 and the second isolation structure 228 may be horizontally spaced apart from one another within the second base structure 222, such that a portion of the second base structure 222 is horizontally interposed (e.g., in the X-direction) between the first isolation structure 226 and the second isolation structure 228. The first isolation structure 226 may be formed of and include a first trench insulative material 227, and the second isolation structure 228 may be formed of and include a second trench insulative material 229. The first isolation structure 226 and the second isolation structure 228 may respectively partially (e.g., less than completely) vertically extend through the second base structure 222 of the second microelectronic device structure 220. In addition, upper boundaries (e.g., upper surfaces) of the first isolation structure 226 and the second isolation structure 228 may be substantially coplanar with one another and with an uppermost boundary (e.g., an uppermost surface) of the second base structure 222.

The first isolation structure 226 may comprise a first trench formed within the second base structure 222 and filled with the first trench insulative material 227. The second isolation structure 228 may comprise a second trench formed within the second base structure 222 and filled with the second trench insulative material 229. The first isolation structure 226 and the second isolation structure 228 may be formed by forming the first trench and the second trench within the second base structure 222, and then filling the first trench with the first trench insulative material 227 and the second trench with the second trench insulative material 229. An etching process used for formation of the second isolation structure 228 may be substantially the same as an etching process used for the formation of the first isolation structure 226; or the etching process used for the formation of the second isolation structure 228 may be different than the etching process used for the formation of the first isolation structure 226. In addition, a material deposition process used for formation of the second isolation structure 228 may be substantially the same as a material deposition process used for the formation of the first isolation structure 226; or the material deposition process used for the formation of the second isolation structure 228 may be different than the material deposition process used for the formation of the first isolation structure 226. In some embodiments, the first isolation structure 226 and the second isolation structure 228 are formed concurrently (e.g., simultaneously) with one another. In other embodiments, the first isolation structure 226 and the second isolation structure 228 are not formed concurrently with one another.

The first isolation structure 226 may be formed to desired dimensions (e.g., vertical height in the Z-direction, length in the Y-direction, width in the X-direction). As a non-limiting example, the first isolation structure 226 may be formed to have a depth (e.g., vertical height in the Z-direction) within a range of from about 100 nm to about 200 nm, such as from about 140 nm to about 200 nm, or from about 120 nm to about 180 nm. In some embodiments, the first isolation structure 226 is formed to have a depth of about 200 nm. As an additional non-limiting example, the first isolation structure 226 may be formed to have horizontal dimensions (e.g., in the X-direction, in the Y-direction) that provide a sufficiently large area to isolate the second base structure 222 from features (e.g., regions, materials, structures, devices, access) subsequently formed and/or bonded on or over the second base structure 222.

The second isolation structure 228 may also be formed to desired dimensions (e.g., vertical height in the Z-direction, length in the Y-direction, width in the X-direction). As a non-limiting example, the second isolation structure 228 may be formed to have a depth (e.g., vertical height in the Z-direction) within a range of from about 100 nm to about 200 nm, such as from about 140 nm to about 200 nm, or from about 120 nm to about 180 nm. In some embodiments, the second isolation structure 228 is formed to have a depth of about 200 nm. As an additional non-limiting example, the second isolation structure 228 may be formed to horizontal dimensions (e.g., in the X-direction, in the Y-direction) that provide a sufficiently large area to isolate the second base structure 222 from features (e.g., regions, materials, structures, devices) subsequently formed and/or bonded on or over the second base structure 222.

Dimensions of the second isolation structure 228 may be substantially the same as corresponding dimensions of the first isolation structure 226; or one or more dimensions of the second isolation structure 228 may be different than the one or more corresponding dimensions of the first isolation structure 226. In some embodiments, the first isolation structure 226 and the second isolation structure 228 have substantially the same vertical height (e.g., depth within the second base structure 222) as one another. In additional embodiments, the first isolation structure 226 and the second isolation structure 228 have different vertical heights (e.g., depths within the second base structure 222) than one another. Furthermore, as shown in FIG. 2B, in some embodiments, at least a horizontal width in the X-direction of the second isolation structure 228 is different than (e.g., greater than) a horizontal width in the X-direction of the first isolation structure 226. In additional embodiments, the horizontal width in the X-direction of the second isolation structure 228 is substantially equal to the horizontal width in the X-direction of the first isolation structure 226.

The second isolation structure 228 horizontally extends in the Y-direction and is horizontally spaced from the first isolation structure 226 in the X-direction by a distance D. In some embodiments, the second isolation structure 228 extends parallel to the first isolation structure 226 in the Y-direction. In addition, the distance D may be selected at least partially based on the horizontal dimensions of the first isolation structure 226 and the second isolation structure 228, as well as desired dimensions of structures to be formed within a third microelectronic device structure following bonding of the first microelectronic device structure 200 to the second microelectronic device structure 220 (as described in further detail below). The distance D between the first isolation structure 226 and the second isolation structure 228 may be selected to control (e.g., mitigate) electrical interactions between structures subsequently formed on or over the first isolation structure 226 (e.g., conductive structures 342 (FIG. 3A, FIG. 3B), conductive pillar structures 346 (FIG. 3A, FIG. 3B), access devices 340 (FIG. 3A, FIG. 3B)) and additional structures subsequently formed on or over the second isolation structure 228 (e.g., storage devices 350 (FIG. 3A, FIG. 3B), conductive plate structures 354 (FIG. 3A, FIG. 3B)). In some embodiments, the distance D between the first isolation structure 226 and the second isolation structure 228 is within a range of from about 100 nm to about 200 nm, such as from about 120 nm to about 200 nm. In addition, the second isolation structure 228 may be at least partially horizontally offset from the first isolation structure 226 in the Y-direction, or the second isolation structure 228 may horizontally overlap the first isolation structure 226 in the Y-direction.

The first trench insulative material 227 of the first isolation structure 226 may be formed of and include insulative material, such as one or more of at least one dielectric oxide material, at least one dielectric nitride material, at least one dielectric oxynitride material, at least one dielectric carbonitride material, at least one dielectric carboxynitride material, at least one dielectric oxycarbide material, and at least one dielectric hydrogenated oxycarbide material. In some embodiments, the first trench insulative material 227 is formed of and includes a dielectric oxide material, such as SiO₂. The first trench insulative material 227 may be substantially homogeneous or may be heterogeneous. In some embodiments, the first trench insulative material 227 is substantially homogeneous. In additional embodiments, the first trench insulative material 227 is heterogeneous.

The second trench insulative material 229 of the second isolation structure 228 may be formed of and include insulative material, such as one or more of at least one dielectric oxide material, at least one dielectric nitride material, at least one dielectric oxynitride material, at least one dielectric carbonitride material, at least one dielectric carboxynitride material, at least one dielectric oxycarbide material, and at least one dielectric hydrogenated oxycarbide material. A material composition of the second trench insulative material 229 may be substantially the same as a material composition of the first trench insulative material 227, or the material composition of the second trench insulative material 229 may be different than the material composition of the first trench insulative material 227. In some embodiments, the second trench insulative material 229 is formed of and includes a dielectric oxide material, such as SiO₂. The second trench insulative material 229 may be substantially homogeneous, or may be heterogeneous. In some embodiments, the second trench insulative material 229 is substantially homogeneous. In additional embodiments, the second trench insulative material 229 is heterogeneous.

Referring next to FIG. 2C, the first microelectronic device structure 200 may be vertically (e.g., in the Z-direction) inverted (e.g., flipped) and attached (e.g., bonded) to the second microelectronic device structure 220 to form a third microelectronic device structure 230 (e.g., an assembly). As shown in FIG. 2C, the third microelectronic device structure 230 may be formed to include the first microelectronic device structure 200 (including the first base structure 202, the stack structure 204 (including a vertically alternating sequence of the first material 208 and the second material 210 arranged in tiers 212), and the first insulative material 206), as vertically inverted, over and bonded to the second microelectronic device structure 220 (including the first isolation structure 226, the second isolation structure 228, and the second base structure 222). Alternatively, the second microelectronic device structure 220 may be vertically inverted (e.g., flipped) and attached (e.g., bonded) to the first microelectronic device structure 200 to form the third microelectronic device structure 230, and thereafter the third microelectronic device structure 230 may be vertically inverted to arrive at the orientation thereof depicted in FIG. 2C.

To form the third microelectronic device structure 230, the first insulative material 206 of the first microelectronic device structure 200 may be provided in physical contact with the first isolation structure 226, the second isolation structure 228, and the second base structure 222 of the second microelectronic device structure 220; and then the first insulative material 206, first isolation structure 226, second isolation structure 228, and the second base structure 222 may be exposed to conditions (e.g., temperatures, pressures, environments, chemistries, precursors) to at least form bonds (e.g., dielectric-to-dielectric bonds, such as one or more of oxide-to-oxide bonds, oxycarbide-to-oxycarbide bonds, carboxynitride-to-carboxynitride bonds, oxycarbide-to-oxide bonds, carboxynitride-to-oxide bonds, carbonitride-to-carbonitride bonds, carboxynitride-to-carbonitride bonds) between the first insulative material 206 and each of the first isolation structure 226 and the second isolation structure 228. The conditions may also form additional bonds (e.g., dielectric-to-semiconductor bonds) between the first insulative material 206 and exposed semiconductor material of the second base structure 222. By way of non-limiting example, the first insulative material 206, the first isolation structure 226, the second isolation structure 228, and the second base structure 222 may be exposed to a temperature greater than or equal to about 400° C. (e.g., within a range of from about 400° C. to about 800° C., greater than about 800° C.) to at least form bonds between the first insulative material 206 and each of the first isolation structure 226 and the second isolation structure 228. In some embodiments, the first insulative material 206, the first isolation structure 226, the second isolation structure 228, and the second base structure 222 are exposed to at least one temperature greater than about 800° C. to at least form oxide-to-oxide bonds between the first insulative material 206 and each of the first isolation structure 226 and the second isolation structure 228.

Providing the first microelectronic device structure 200 and the second microelectronic device structure 220 in physical contact with one another ahead of bonding the first microelectronic device structure 200 and the second microelectronic device structure 220 to form the third microelectronic device structure 230 may include facilitating one or more different arrangements (e.g., positions, orientations, alignments) of the first microelectronic device structure 200 relative to the second microelectronic device structure 220. By way of non-limiting example, the first microelectronic device structure 200 may or may not be horizontally rotated (e.g., positivity horizontally rotated, negatively horizontally rotated) about an axis (e.g., an axis parallel to the Z-direction) relative to the second microelectronic device structure 220, or vice versa. One or more of the second microelectronic device structure 220 and the first microelectronic device structure 200 may include alignment markers to facilitate desired arrangements of features of the second microelectronic device structure 220 and the first microelectronic device structure 200 ahead of bonding the second microelectronic device structure 220 and the first microelectronic device structure 200.

While FIG. 2C, FIG. 2D, and FIG. 2E depict the first insulative material 206, the first isolation structure 226, and the second isolation structure 228 as three individually shaded and separate regions before the bonding process, the first insulative material 206, the first isolation structure 226, and the second isolation structure 228 may be integral and continuous following the bonding process. A bonded insulative material 233 including the first insulative material 206, the first trench insulative material 227 of the first isolation structure 226, and the second trench insulative material 229 of the second isolation structure 228 may be substantially homogeneous, or the bonded insulative material 233 may be heterogeneous. In some embodiments, the bonded insulative material 233 is free of a bond line. In other embodiments, the bonded insulative material 233 has at least one bond line. In yet other embodiments, bonding the first insulative material 206 to the first isolation structure 226 and to the second isolation structure 228 may form an interface material between remaining portions of the first insulative material 206 and the first isolation structure 226 and/or between remaining portions of the first insulative material 206 and the second isolation structure 228; and the interface material has a different material composition than each of the first insulative material 206, the first isolation structure 226, and the second isolation structure 228. For example, if the first insulative material 206, the first trench insulative material 227, and the second trench insulative material 229 respectively include dielectric oxycarbide material, bonding the first insulative material 206 to the first trench insulative material 227 and the second trench insulative material 229 may form a dielectric oxide interface material between the first insulative material 206 and each of the first trench insulative material 227 and the second trench insulative material 229.

The bonded insulative material 233 of the third microelectronic device structure 230 may be formed to a desired maximum vertical height (e.g., in the Z-direction). Within a horizontal area of the first isolation structure 226, the bonded insulative material 233 of the third microelectronic device structure 230 has a vertical height substantially equal to combined vertical heights of the first insulative material 206 and the first isolation structure 226. For example, if the first insulative material 206 and the first isolation structure 226 are each formed to a vertical height of about 100 nm, within the horizontal area of the first isolation structure 226, the bonded insulative material 233 may have a vertical height of about 200 nm. Similarly, within a horizontal area of the second isolation structure 228, the bonded insulative material 233 of the third microelectronic device structure 230 has a vertical height substantially equal to combined vertical heights of the first insulative material 206 and the second isolation structure 228. For example, if the first insulative material 206 and the second isolation structure 228 are each formed to a vertical height of about 100 nm, within the horizontal area of the second isolation structure 228, the bonded insulative material 233 may have a vertical height of about 200 nm. The bonded insulative material 233 of the third microelectronic device structure 230 may have a variable (e.g., non-uniform) vertical height, where portions thereof within horizontal areas of the first isolation structure 226 and the second isolation structure 228 have relatively greater vertical heights than other portions thereof outside of the horizontal areas of the first isolation structure 226 and the second isolation structure 228.

Referring to FIG. 2D, the first base structure 202 of the third microelectronic device structure 230 may be substantially removed (e.g., using one or more of dry etching, wet etching, ion milling, CMP, laser ablation, smart cutting, and another material removal process). In some embodiments, following the formation of the third microelectronic device structure 230, the first base structure 202 is the vertically (e.g., in the Z-direction) uppermost material of the third microelectronic device structure 230, and a CMP process is used to substantially remove the first base structure 202 of the third microelectronic device structure 230. In other embodiments, following the formation of the third microelectronic device structure 230, the first base structure 202 is the vertically (e.g., in the Z-direction) lowermost material of the third microelectronic device structure 230, and a laser ablation process is used to remove the first base structure 202 of the third microelectronic device structure 230.

Referring next to FIG. 2E, a first trench 234 and a second trench 236 may be formed in substantially the same manner as the first trench 134 and the second trench 136 at the processing stage previously described with reference to FIG. 1E, except that the first trench 234 is formed to horizontally overlap (e.g., in the X-direction) a horizontal area of the first isolation structure 226, and the second trench 236 is formed to horizontally overlap (e.g., in the X-direction) a horizontal area of the second isolation structure 228. The first trench 234 and the second trench 236 may be horizontally offset from one another, and may respectively vertically extend to or into the bonded insulative material 233. As described in further detail below, the bonded insulative material 233 may serve as an etch stop material during the formation of the first trench 234 and the second trench 236, and may also electrically isolate the second base structure 222 from features (e.g., materials, structures, circuitry, devices) subsequently formed within the first trench 234 and the second trench 236.

The first trench 234 and the second trench 236 may respectively be formed using at least one etching process, such as an anisotropic etching process (e.g., a deep reactive ion etching (DRIE)) that removes portions of the stack structure 204. As previously mentioned, the bonded insulative material 233 may serve as an etch stop material for the etching process. Following the etching process, portions of the bonded insulative material 233 within horizontal areas of the first isolation structure 226 and the second isolation structure 228 may be exposed by the first trench 234 and the second trench 236. Exposed surfaces of the stack structure 204 and the bonded insulative material 233 may at least partially define boundaries (e.g., horizontal boundaries, vertical boundaries) of the first trench 234 and the second trench 236.

In some embodiments, a horizontal area of the first trench 234 is less than or equal to the horizontal area of the first isolation structure 226. However, this disclosure is not so limited, and at least one horizontal dimension (e.g., width in the X-direction and/or length in the Y-direction) of the first trench 234 may be greater than at least one corresponding horizontal dimensions of the first isolation structure 226. Moreover, a horizontal center (e.g., in the X-direction) of the first trench 234 may be substantially aligned with a horizontal center (e.g., in the X-direction) of the first isolation structure 226. However, this disclosure is not so limited, and the horizontal center of the first trench 234 may be offset (e.g., in the X-direction) from the horizontal center (e.g., in the X-direction) of the first isolation structure 226.

In some embodiments, a horizontal area of the second trench 236 is less than or equal to the horizontal area of the second isolation structure 228. However, this disclosure is not so limited, and at least one horizontal dimension (e.g., width in the X-direction and/or length in the Y-direction) of the second trench 236 may be greater than at least one corresponding horizontal dimension of the second isolation structure 228. Moreover, a horizontal center (e.g., in the X-direction) of the first trench 234 may be substantially aligned with a horizontal center (e.g., in the X-direction) of the second isolation structure 228. However, this disclosure is not so limited, and the horizontal center of the second trench 236 may be offset (e.g., in the X-direction) from the horizontal center (e.g., in the X-direction) of the second isolation structure 228.

The first trench 234 and the second trench 236 may respectively be formed to have desired horizontal cross-section dimensions (e.g., a length in the Y-direction, a width in the X-direction) and a desired horizontal cross-sectional shape. As a non-limiting example, the first trench 234 may be formed to have horizontal dimensions that facilitate additional processing of the third microelectronic device structure 230 to form a vertical (e.g., in the Z-direction) stack of access devices 340 (FIG. 3A, FIG. 3B) within the stack structure 204 of the third microelectronic device structure 230. As another non-limiting example, the second trench 236 may be formed to have horizontal dimensions that facilitate additional processing of the third microelectronic device structure 230 to form a vertical (e.g., in the Z-direction) stack of storage devices 350 (FIG. 3A, FIG. 3B) within the stack structure 204 of the third microelectronic device structure 230. Horizontal dimensions (and, hence, a horizontal area) of the second trench 236 may be substantially equal to horizontal dimensions (and, hence, a horizontal area) of the first trench 234 of the third microelectronic device structure 230; or one or more horizontal dimensions (e.g., a length, a width) (and, potentially, a horizontal area) of the second trench 236 may be different than one or more corresponding horizontal dimensions (e.g., a length, a width) (and, potentially, a horizontal area) of the first trench 234 of the third microelectronic device structure 230.

The first trench 234 and the second trench 236 may respectively horizontally extend in a first direction (e.g., in the Y-direction), and may be horizontally spaced from one another in a second direction (e.g., in the X-direction) orthogonal to the first direction. In some embodiments, the second trench 236 and the first trench 234 horizontally extend in parallel in the Y-direction. In addition, the second trench 236 may be at least partially horizontally offset from the first trench 234 in the Y-direction, or the second trench 236 may substantially horizontally overlap the first trench 234 in the Y-direction.

Following the formation of the first trench 234 and the second trench 236, the third microelectronic device structure 230 may be subject to additional processing, as desired. As a non-limiting example, a vertical stack of access devices 340 (FIG. 3A, FIG. 3B), and/or a vertical stack of storage devices 350 (FIG. 3A, FIG. 3B), and/or interconnect structures (e.g., digit lines (e.g., conductive pillar structures 346 (FIG. 3A, FIG. 3B)), word lines (e.g., conductive structures 342 (FIG. 3A, FIG. 3B)), contact structures) may be formed within the third microelectronic device structure 230 to form arrays of memory cells 360 (FIG. 3A, FIG. 3B). As an additional non-limiting example, BEOL structures (e.g., routing structures, pad structures, contact structures) (FIG. 3B) and/or control logic devices (e.g., MUX, decoders (e.g., local I/O devices), sense amplifiers, ECC devices) (FIG. 3B) may be formed and/or attached (e.g., bonded) over or under the third microelectronic device structure 230, as desired. While FIG. 2E shows the third microelectronic device structure 230 as being formed upon the attachment of the first microelectronic device structure 200 to the second microelectronic device structure 220, the formation of the first trench 234, and the formation of the second trench 236, it will be understood that such additional processing may be implemented to finalize or ready the third microelectronic device structure 230 for inclusion in a relatively larger device and/or electronic system.

The method of forming the third microelectronic device structure 230 described herein with reference to FIGS. 2A through 2E may facilitate the same advantages previously described herein in relation to the method of forming the third microelectronic device structure 130 (FIG. 1E).

Thus, in accordance with embodiments of the disclosure, a microelectronic device includes a first microelectronic device structure and a second microelectronic device structure vertically underlying the first microelectronic device structure. The first microelectronic device structure includes a stack structure and a first insulative material vertically underlying the stack structure. The stack structure includes tiers vertically stacked relative to one another and respectively including a first semiconductor material, and a second semiconductor material vertically neighboring the first semiconductor material. The second microelectronic device structure includes a second insulative material and a base semiconductor structure. The second insulative material is bonded to the first insulative material of the first microelectronic device structure. The base semiconductor structure is at least partially vertically adjacent to and in physical contact with the second insulative material.

Furthermore, in accordance with embodiments of the disclosure, a method of forming a microelectronic device includes forming a first microelectronic device structure including a first base structure, a stack structure vertically overlying the first base structure and comprising a vertically alternating sequence of semiconductor material and additional semiconductor material, and a first insulative material vertically overlying the stack structure. A second microelectronic device structure is formed separate from the first microelectronic device structure. The second microelectronic device structure includes a second base structure, and a second insulative material on the second base structure. The first insulative material of the first microelectronic structure is bonded to the second insulative material of the second microelectronic structure to form an assembly. The first base structure is removed after forming the assembly. Trenches are formed to vertically extend through the stack structure after removing the first base structure. Lower boundaries of the trenches are above an uppermost boundary of the second base structure. A vertical stack of memory cells is formed within the stack structure after forming the trenches.

FIG. 3A and FIG. 3B are simplified, partial, vertical, cross-sectional views illustrating a microelectronic device 300 at processing stages subsequent to that of FIG. 1E, if the microelectronic device 300 is formed from the third microelectronic device structure 130, or at processing stages subsequent to that of FIG. 2E, if the microelectronic device 300 is formed from the third microelectronic device structure 230. The microelectronic device 300 depicted in FIG. 3A and FIG. 3B incorporates the processing acts and features previously described in relation to the formation of the third microelectronic device structure 130 (FIG. 1A through FIG. 1E) or to the formation of the third microelectronic device structure 230 (FIG. 2A through FIG. 2E). To avoid repetition, not all features shown in FIG. 3A and FIG. 3B are described in detail herein. Rather, unless described otherwise, in FIG. 3A and FIG. 3B, features (e.g., structures, materials, regions, devices) substantially similar to features previously described with reference to one or more of FIG. 1A through FIG. 2E are referred to with similar reference numerals incremented by 100.

As shown in FIG. 3A, if formed from the third microelectronic device structure 130 (FIG. 1E), the microelectronic device 300 may be formed to include a base structure 322, a first insulative material 331 corresponding to the third insulative material 132 (FIG. 1E) formed on or over the base structure 322, a stack structure 304 formed on or over the first insulative material 331, a first trench 334 formed into the stack structure 304, a second trench 336 formed into the stack structure 304, and the following features (e.g., regions, materials, structures, devices) formed on or over the first insulative material 331 and/or within the stack structure 304: access devices 340 including channel regions 341, conductive structures 342, and first dielectric materials 343; second insulative materials 344; third insulative materials 345; conductive pillar structures 346; a fourth insulative material 347; storage devices 350 including second dielectric materials 351, first electrode materials 352, and second electrode materials 353; and a conductive plate structure 354. Otherwise, if formed from the third microelectronic device structure 230 (FIG. 2E), the microelectronic device 300 may be formed to include a base structure 322; a first insulative material 331 corresponding to the bonded insulative material 233 (FIG. 2E) (e.g., including the first insulative material 206 (FIG. 2E), the first trench insulative material 227 (FIG. 2E) of the first isolation structure 226 (FIG. 2E), and the second trench insulative material 229 (FIG. 2E) of the second isolation structure 228 (FIG. 2E)) a stack structure 304; a first trench 334 formed into the stack structure 304; a second trench 336 formed into the stack structure 304; and the following features (e.g., regions, materials, structures, devices) formed on or over the first insulative material 331 and/or within the stack structure 304: access devices 340 including channel regions 341, conductive structures 342, and first dielectric materials 343; second insulative materials 344; third insulative materials 345; conductive pillar structures 346; a fourth insulative material 347; storage devices 350 including second dielectric materials 351, first electrode materials 352, and second electrode materials 353; and a conductive plate structure 354.

In some embodiments, each access device 340 of the vertical stacks of access devices 340 is horizontally neighbored (e.g., in the X-direction) by a storage device 350 of a corresponding vertical stack of storage devices 350 to form a vertical stack of memory cells 360. Each memory cell 360 includes one of the storage devices 350 in contact with a horizontally neighboring access device 340. For example, the first electrode material 352 of the storage device 350 may contact the access device 340. In some embodiments, each memory cell 360 comprises a dynamic random access memory (DRAM) cell. Each memory cell 360 individually includes a storage device 350 horizontally neighboring an access device 340 of the same level. Accordingly, the vertical stack of memory cells 360 includes vertically neighboring (e.g., in the Z-direction) levels of memory cells 360, each level of memory cells 360 including an access device 340 and a horizontally neighboring storage device 350. In other words, each vertical stack of memory cells 360 comprises vertically spaced (e.g., in the Z-direction) levels of memory cells 360, each vertical level of each vertical stack of memory cells 360 including a vertical level of a vertical stack of access devices 340 and a vertical level of a vertical stack of storage devices 350. Stated another way, each vertical stack of memory cells 360 includes a vertical stack of access devices 340 and a vertical stack of storage devices 350, the storage devices 350 of the vertical stack of storage devices 350 coupled to the access devices 340 of the vertical stack of access devices 340. Additionally, the vertical stack of access devices 340 may horizontally neighbor (e.g., in the Y-direction) the vertical stack of storage devices 350.

Moreover, in additional embodiments, an individual memory cell 360 may be formed to include more than one (e.g., two (2)) access devices 340 and one storage device 350 forming different memory cell arrangements (e.g., such as the so-called 2T-1C configuration). Additionally, in further embodiments, the access devices 340 may be coupled to the storage devices 350 by means of interconnect structures and/or additional regions (e.g., semiconductive regions, conductive regions). Furthermore, in additional embodiments, an individual memory cell 360 may be formed to include an access device 340 vertically offset from a storage device 350, such that the access device 340 is located in a different vertical level than the storage device 350.

An individual vertical stack of access devices 340 may be formed at least partially within a horizontal area of the first trench 334, and may include vertically spaced (e.g., in the Z-direction) access devices 340 (e.g., transistors), each formed within stack structure 304. The access devices 340 may comprise doped portions of at least one material of the stack structure 304 (e.g., the first material 108 (FIG. 1E), the first material 208 (FIG. 2E), the second material 110 (FIG. 1E), the second material 210 (FIG. 2E)) to form channel regions 341. The channel regions 341 may be doped with one or more of at least one N-type dopant, such as one or more of arsenic ions, phosphorous ions, and antimony ions. In other embodiments, the channel regions 341 are doped with at least one P-type dopant, such as one or more of boron ions, aluminum ions, and gallium ions. In some embodiments, the channel regions 341 of the access devices 340 are horizontally between (e.g., in the X-direction, in the Y-direction) a source region and a drain region of the access devices 340.

The conductive structures 342 may be formed to vertically neighbor (e.g., in the Z-direction) and horizontally overlap (e.g., in the X-direction) the channel regions 341 of the access devices 340, and may serve as word lines (e.g., local word lines) for the microelectronic device 300. A portion of an individual conductive structure 342 vertically neighboring and horizontally overlapping a channel region 341 of an individual access device 340 may serve as a gate electrode for the access device 340.

The conductive structures 342 may individually be formed of and include conductive material. In some embodiments, the conductive structures 342 are individually formed of and include W. In other embodiments, the conductive structures 342 are individually formed of and include TiN. In yet other embodiments, the conductive structures 342 are individually formed of and include Mo. In additional embodiments, the conductive structures 342 are individually formed of and include Cu.

In some embodiments, the second insulative material 344 is formed of and includes one or more of the materials described above with reference to the first insulative material 106 (FIG. 1A). As a non-limiting example, in some embodiments, the second insulative material 344 is formed of and includes dielectric oxide material (e.g., SiO₂).

Each of the channel regions 341 is at least partially surrounded by a first dielectric material 343, which may also be referred to herein as a “gate dielectric material.” In some embodiments, the conductive structures 342 are separated from the channel regions 341 by the first dielectric material 343. The first dielectric material 343 may be formed of and include insulative material. In some embodiments, the first dielectric material 343 is formed of and includes dielectric oxide material (e.g., SiO₂).

Vertically neighboring (e.g., in the Z-direction) access devices 340 may be vertically spaced from one another by a third insulative material 345. In some embodiments, the third insulative material 345 surrounds at least a portion of the first dielectric material 343. The third insulative material 345 may be formed of and includes insulative material. In some embodiments, the third insulative material 345 is formed of and includes one of more of a dielectric nitride material (e.g., Si₃N₄) and a dielectric oxynitride material (e.g., silicon oxynitride).

Conductive pillar structures 346 may be positioned within a horizontal area of the first trench 334 and may vertically extend through the stack structure 304 of the microelectronic device 300. The conductive pillar structures 346 may be employed as digit lines or digit line contact structures for the microelectronic device 300. Each conductive pillar structure 346 may be operatively associated with an individual vertical stack of access devices 340. In some embodiments, the conductive pillar structures 346 horizontally neighbor (e.g., in the X-direction) source/drain regions of the access devices 340 of an individual vertical stack of the access devices 340. The conductive pillar structures 346 may individually be formed of and include conductive material. In some embodiments, the conductive pillar structures 346 are individually formed of and include W.

The fourth insulative material 347 is formed within a horizontal area of the first trench 334 and may electrically isolate the horizontally spaced conductive pillar structures 346. The fourth insulative material 347 may be formed of and include insulative material. In some embodiments, the fourth insulative material 347 is formed of and includes dielectric oxide material (e.g., SiO₂).

An individual vertical stack of storage devices 350 may be formed at least partially within a horizontal area of the second trench 336, and may include vertically spaced (e.g., in the Z-direction) storage devices 350 (e.g., capacitors).

Each storage device 350 may include a first electrode material 352, a second electrode material 353, and a second dielectric material 351 between the first electrode material 352 and the second electrode material 353. In some embodiments, the storage devices 350 are capacitors.

The first electrode material 352 of an individual storage device 350 of an individual memory cell 360 may be formed to horizontally neighbor (e.g., in the X-direction) an individual access device 340 of the memory cell 360. The first electrode material 352 may be formed of and include conductive material.

The second dielectric material 351 of an individual storage device 350 of an individual memory cell 360 may be formed on or over the first electrode material 352 of the storage device 350. The second dielectric material 351 may be formed of and include insulative material.

The second electrode material 353 of an individual storage device 350 of an individual memory cell 360 may be formed on or over the second dielectric material 351 of the storage device 350. The second electrode material 353 may be formed of and include conductive material. In some embodiments, the second electrode material 353 is formed of substantially the same material as the first electrode material 352.

The conductive plate structures 354 may individually be in contact with the second electrode materials 353 of the storage devices 350 of horizontally neighboring vertical stacks of storage devices 350 of horizontally neighboring vertical stacks of memory cells 360. Accordingly, each of the storage devices 350 of the vertical stack of storage devices 350 may be in contact with a conductive plate structure 354 vertically extending (e.g., in the Z-direction) through the stack structure 304 of the microelectronic device 300. In some embodiments, the second electrode materials 353 are substantially integral with the conductive plate structures 354. In some embodiments, the second electrode materials 353 of horizontally neighboring (e.g., in the X-direction) vertical stacks of storage devices 350 of vertical stacks of memory cells 360 are in contact with the same conductive plate structure 354. In some embodiments, the second electrode materials 353 of horizontally neighboring (e.g., in the Y-direction) vertical stacks of storage devices 350 that directly horizontally neighbor (e.g., in the Y-direction) one another and are not separated by, for example, an access device 340, are in contact with the same conductive plate structure 354.

The conductive plate structures 354 are individually formed of conductive material. In some embodiments, the conductive plate structures 354 comprise substantially the same material composition as the second electrode material 353 of the storage devices 350. In other embodiments, the conductive plate structures 354 have a different material composition than that of the second electrode material 353 of the storage devices 350.

Still referring to FIG. 3A, in some embodiments, the first trench 334 is horizontally (e.g., in the Y-direction) segmented (e.g., divided, separated) into multiple first trenches 334 separated from one another by insulative material, and the second trench 336 is horizontally (e.g., in the Y-direction) segmented (e.g., divided, separated) into multiple second trenches 336 separated from one another by insulative material. In such embodiments, different arrays of memory cells 360 are horizontally (e.g., in the Y-direction) separated from one another by insulative material.

Referring next to FIG. 3B, one or more control circuitry structures 370 may be provided (e.g., formed, bonded) vertically over and/or vertically under the array of memory cells 360 of the microelectronic device 300. As described in further detail below, the control circuitry structure(s) 370 may include control logic circuitry operatively associated with the memory cells 360 of the microelectronic device 300. FIG. 3B illustrates the control circuitry structure(s) 370 as dashed blocks structures to comprise all possible positional variations and/or positional combinations for the control circuitry structure(s) 370.

The control circuitry structures 370 may individually include control logic circuitry and devices configured to effectuate control operations for the memory cells 360 of the microelectronic device 300. By way of non-limiting example, the control circuitry structures 370 may include one or more of (e.g., all of) sense amplifier devices (e.g., equalization (EQ) amplifiers, isolation (ISO) amplifiers, NMOS sense amplifiers (NSAs), PMOS sense amplifiers (PSAs)), column decoders, multiplexer control logic devices, sense amplifier drivers, main word line driver devices, row decoder devices, row select devices, so-called “back-end-of-line” (BEOL) structures (e.g., routing structures, pad structures, contact structures), charge pumps (e.g., V_{ccp} charge pumps, V_{negwl} charge pumps, DVC2 charge pumps), delay-locked loop (DLL) circuitry (e.g., ring oscillators), Vad regulators, drivers (e.g., string drivers, main word line drivers (MWD), sub word line drivers (SWD)), page buffers, decoders (e.g., local I/O devices), memory test devices, array multiplexers (MUX), error checking and correction (ECC) devices, self-refresh/wear leveling devices, other chip/deck control circuitry, and/or other microelectronic devices (e.g., integrated circuits (ICs)).

In some embodiments, an individual control circuitry structure 370 includes one or more sense amplifier (SA) regions vertically offset from (e.g., in the Z-direction) and within horizontal areas of the vertical stacks of memory cells 360. In such embodiments, the SA regions include SA devices (e.g., equalization (EQ) amplifiers, isolation (ISO) amplifiers, NMOS sense amplifiers (NSAs), PMOS sense amplifiers (PSAs)) in electrical communication with the vertical stacks of memory cells 360. In additional embodiments, the control circuitry structures 370 include one or more sub word line driver (SWD) regions vertically offset from (e.g., in the Z-direction) and within horizontal areas of the vertical stacks of memory cells 360. In such embodiments, the SWD regions include SWD devices in electrical communication with the vertical stacks of memory cells 360.

In some embodiments, the control circuitry structure(s) 370 are formed separately from a structure including the array of memory cells 360, and are then subsequently attached (e.g., bonded, such as dielectric-to-dielectric bonded; or dielectric-to-dielectric bonded and metal-to-metal bonded, in combination) to the structure including the array of memory cells 360 in a manner facilitating operable communication between the array of memory cells 360 and a control logic circuitry of the control circuitry structure(s) 370.

Thus, in accordance with embodiments of the disclosure, a memory device includes a first structure, a second structure vertically underlying and bonded to the first structure, and a third structure vertically offset from the first structure and the second structure. The first structure includes a stack structure having tiers vertically stacked relative to one another, the tiers respectively comprising silicon and silicon-germanium vertically adjacent to the silicon; vertical stacks of dynamic random access memory (DRAM) cells within the stack structure; and a first insulative material vertically underlying the stack structure. The second structure includes a base semiconductor structure; and a second insulative material at least partially covering the base semiconductor structure and dielectric-to-dielectric bonded to the first insulative material of the first microelectronic device structure. The third structure includes control logic circuitry operatively associated with the vertical stacks of DRAM cells of the first structure.

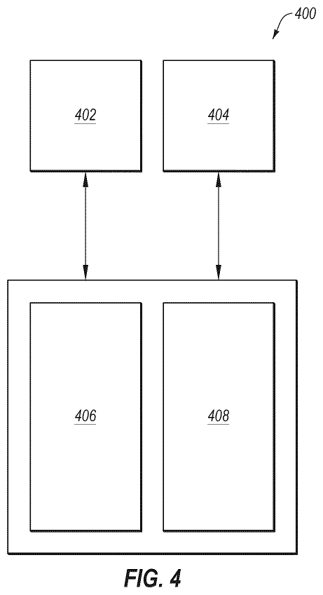

Microelectronic devices (e.g., the microelectronic device 300 (FIG. 3B)), in accordance with embodiments of the disclosure, may be used in embodiments of electronic systems of the disclosure. For example, FIG. 4 is a block diagram illustrating an electronic system 400 according to embodiments of the disclosure. The electronic system 400 may include, for example, a computer or computer hardware component, a server or other networking hardware component, a cellular telephone, a digital camera, a personal digital assistant (PDA), a portable media (e.g., music) player, a Wi-Fi or cellular-enabled tablet such as, for example, an iPAD® or SURFACE® tablet, an electronic book, a navigation device, a smartphone, a smartwatch, a virtual reality (VR) device (e.g., headset), etc. The electronic system 400 includes at least one memory device 408. The memory device 408 may include, for example, a microelectronic device (e.g., the microelectronic device 300 (FIG. 3B)) previously described herein. The electronic system 400 may further include at least one electronic signal processor device 406 (often referred to as a “microprocessor”). The electronic signal processor device 406 may, optionally, include a microelectronic device (e.g., the microelectronic device 300 (FIG. 3B)) previously described herein. While the memory device 408 and the electronic signal processor device 406 are depicted as two (2) separate devices in FIG. 4, in additional embodiments, a single (e.g., only one) memory/processor device having the functionalities of the memory device 408 and the electronic signal processor device 406 is included in the electronic system 400. In such embodiments, the memory/processor device may include a microelectronic device (e.g., the microelectronic device 300 (FIG. 3B)) previously described herein. The electronic system 400 may further include one or more input devices 402 for inputting information into the electronic system 400 by a user, such as, for example, a mouse or other pointing device, a keyboard, a touchpad, a button, a control panel, or an additional electronic system (e.g., an electronic system similar to the electronic system 400). The electronic system 400 may further include one or more output devices 404 for outputting information (e.g., visual output, audio output, data output) to a user such as, for example, a monitor, a display, a printer, an audio output jack, a speaker, an additional electronic system (e.g., an electronic system similar to the electronic system 400), etc. In some embodiments, the input device 402 and the output device 404 comprise a single touchscreen device that can be used both to input information to the electronic system 400 and to output visual information to a user. The input device 402 and the output device 404 may communicate electrically with one or more of the memory device 408 and the electronic signal processor device 406.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A microelectronic device, comprising:
a first microelectronic device structure comprising:
a stack structure comprising:
tiers vertically stacked relative to one another and respectively including:
a first semiconductor material; and
a second semiconductor material vertically neighboring the first semiconductor material; and
a first insulative material vertically underlying the stack structure; and
a second microelectronic device structure vertically underlying the first microelectronic device structure and comprising:
a second insulative material bonded to the first insulative material of the first microelectronic device structure; and
a base semiconductor structure at least partially vertically adjacent to and in physical contact with the second insulative material.

2. The microelectronic device of claim 1, wherein the first microelectronic device structure further comprises vertical stacks of volatile memory cells within the stack structure.

3. The microelectronic device of claim 1, wherein the first insulative material has vertical thickness within a range of from about 100 nm to about 200 nm.

4. The microelectronic device of claim 3, wherein the second insulative material has an additional vertical thickness within a range of from about 100 nm to about 200 nm.

5. The microelectronic device of claim 4, wherein a combined, maximum vertical thickness of the first insulative material and the second insulative material is within a range of from about 200 nm to about 300 nm.

6. The microelectronic device of claim 1, wherein a bonded insulative material comprising the first insulative material and the second insulative material has a substantially uniform vertical thickness.

7. The microelectronic device of claim 1, wherein a bonded insulative material comprising the first insulative material and the second insulative material has variable vertical thicknesses across horizonal dimensions thereof.

8. The microelectronic device of claim 1, wherein the second insulative material of the second microelectronic device structure comprises:
a first portion vertically extending into the base semiconductor structure; and a second portion horizontally offset and discrete from the first portion, the second portion also vertically extending into the base semiconductor structure.

9. The microelectronic device of claim 8, wherein upper boundaries of the first portion and the second portion of the second insulative material are substantially coplanar with an uppermost boundary of the base semiconductor structure.

10. The microelectronic device of claim 9, wherein the first microelectronic device structure further comprises:
a stack of access devices at least partially within a horizontal area of the first portion of the second insulative material; and
a stack of storage devices coupled to the stack of access devices and at least partially within a horizontal area of the second portion of the second insulative material.

11. The microelectronic device of claim 1, wherein the stack structure includes greater than or equal to eighty (80) of the tiers.

12. The microelectronic device of claim 1, wherein:
the first semiconductor material comprises epitaxial silicon; and
the second semiconductor material comprises epitaxial silicon germanium (SiGe).

13. The microelectronic device of claim 1, further comprising conductive structures vertically extending completely through the stack structure of the first microelectronic device structure, a bonded insulative material including the first insulative material and the second insulative material vertically interposed between and electrically isolating the base semiconductor structure from the conductive structures.

14. A method of forming a microelectronic device, comprising:
forming a first microelectronic device structure comprising:
a first base structure;
a stack structure vertically overlying the first base structure and comprising a vertically alternating sequence of semiconductor material and additional semiconductor material; and
a first insulative material vertically overlying the stack structure;
forming a second microelectronic device structure separate from the first microelectronic device structure, the second microelectronic device structure comprising:
a second base structure; and
a second insulative material on the second base structure;
bonding the first insulative material of the first microelectronic device structure to the second insulative material of the second microelectronic device structure to form an assembly;
removing the first base structure after forming the assembly;
forming trenches vertically extending through the stack structure after removing the first base structure, lower boundaries of the trenches above an uppermost boundary of the second base structure; and
forming a vertical stack of memory cells within the stack structure after forming the trenches.

15. The method of claim 14, further comprising forming the second base structure of the second microelectronic device structure to comprise semiconductor material.

16. The method of claim 15, further comprising forming the second insulative material horizontally extending substantially continuously over an entity of the semiconductor material of the second base structure.

17. The method of claim 15, further comprising forming the second insulative material to vertically extend into the semiconductor material of the second base structure.

18. The method of claim 17, further comprising forming the second insulative material to comprise a first portion and a second portion discontinuous with the first portion, a section of the semiconductor material of the second base structure vertically overlapping and horizontally extending between the first portion and the second portion of the second insulative material.

19. The method of claim 14, forming a vertical stack of memory cells within the stack structure comprises:
forming a vertical stack of access devices for the vertical stack of memory cells to at least partially horizontally overlap and fill one of the trenches; and
forming a vertical stack of storage devices for the vertical stack of memory cells to at least partially horizontally overlap and fill another one of the trenches.

20. A memory device, comprising:
a first structure comprising:
a stack structure having tiers vertically stacked relative to one another, the tiers respectively comprising silicon and silicon-germanium vertically adjacent to the silicon;
vertical stacks of dynamic random access memory (DRAM) cells within the stack structure;
a first insulative material vertically underlying the stack structure;
a second structure vertically underlying and bonded to the first structure and comprising:
a base semiconductor structure; and
a second insulative material at least partially covering the base semiconductor structure and dielectric-to-dielectric bonded to the first insulative material of the first structure; and
a third structure vertically offset from the first structure and the second structure and comprising control logic circuitry operatively associated with the vertical stacks of DRAM cells of the first structure.
